(19) United States
(12) Patent Application Publication
(10) Pub. No.: US 2009/0257180 A1
(43) Pub. Date: Oct. 15, 2009

(54) Portable Electronic Book System

(76) Inventors: Venita Davis, Jacksonville, FL (US); Dewayne Davis, Jacksonville, FL (US)

Correspondence Address: JAY M. SCHLOFF;INTELLIPEX PLLC, 30200 TELEGRAPH RD, SUITE 245, BINGHAM FARMS, MI, 48025, US

(21) Appl. No.: 12/102,054

(22) Filed: Apr. 14, 2008

(51) Int. Cl. G06F 1/16; H05K 5/00; H05K 7/00

(52) U.S. Cl. 361/679.26

(57) ABSTRACT

A portable electronic book system is disclosed. The portable electronic book system includes at least one receiving module, a memory module, a processing module, and a display module. The at least one receiving module is to receive an electronic data from at least one machine readable storage medium. The electronic data is associated with content of at least one textbook of a user. The memory module is operatively coupled to the at least one receiving module. The memory module is adapted to store the electronic data received from the at least one receiving module. The processing module is operatively coupled to the memory module. The processing module is adapted to retrieve the stored electronic data from the memory module and process the retrieved electronic data. The display module is operatively coupled to the processing module and adapted to display the processed electronic data.

### FIELD OF THE INVENTION

The present invention relates generally to electronic systems, and, more particularly, to a portable electronic book system adapted to receive data from a data source and display the data to a user.

### BACKGROUND OF THE INVENTION

Students all over the world are required to carry their text books to academic institutions, such as schools, colleges and the like. Generally, the text books are very heavy and accordingly it is very cumbersome for the students, and more specifically for small children, to carry the text books to the school. Children often utilize bags, such as backpacks, for carrying the text books. However, the weight of the text books makes the bags very bulky, thereby resulting in wear and tear of the bags. Accordingly, the bags may be required to be repaired very frequently, which may be time consuming and costly for the parents of the children. Moreover, after subsequent repairs the bag may be rendered useless and may have to be replaced with a new bag.

Furthermore, the children may find it difficult to carry the heavy bags. More specifically, it may be strenuous for the children to carry the heavy bags on their backs and shoulders.

Accordingly, based on the foregoing, there is a need for a system that may enable children to conveniently access their text books without requiring them to carry the text books in their bags. Further there is a need for a system that is easily portable, thereby avoiding the need of carrying a bulky bag.

### SUMMARY OF THE INVENTION

In view of the foregoing disadvantages inherent in the prior art, the general purpose of the present invention is to provide a portable electronic book system configured to include all the advantages of the prior art, and to overcome the drawbacks inherent therein.

Accordingly, an object of the present invention is to provide a portable electronic book system, which avoids a need for students to carry text books for accessing them in their schools.

Another object of the present invention is to provide a portable electronic book system, which can be easily carried by a user such as a child.

In light of the above objects, in one aspect of the present invention, a portable electronic book system is disclosed. The portable electronic book system includes at least one receiving module, a memory module operatively coupled to the at least one receiving module, a processing module operatively coupled to the memory module, and a display module operatively coupled to the processing module. The at least one receiving module is adapted to receive an electronic data from at least one machine readable storage medium. The electronic data is associated with content of at least one textbook of a user. The memory module is adapted to store the electronic data received from the at least one receiving module. The processing module is adapted to retrieve the stored electronic data from the memory module, and process the retrieved electronic data. The display module is adapted to display the processed electronic data.

In another aspect of the present invention, the display module is configured as a touch screen display thereby enabling a user to request for the electronic data through the touch screen display.

These together with other aspects of the present invention, along with the various features of novelty that characterize the present invention, are pointed out with particularity in the claims annexed hereto and form a part of this present invention. For a better understanding of the present invention, its operating advantages, and the specific objects attained by its uses, reference should be made to the accompanying drawings and descriptive matter in which there are illustrated exemplary embodiments of the present invention.

### BRIEF DESCRIPTION OF THE DRAWINGS

The advantages and features of the present invention will become better understood with reference to the following detailed description and claims taken in conjunction with the accompanying drawings, wherein like elements are identified with like symbols, and in which:

FIG. 1 illustrates a block diagram of a portable electronic book system, in accordance with an embodiment of the present invention;

FIG. 2 illustrates a perspective view of an electronic book incorporating the potable electronic book system of FIG. 1, in accordance with an exemplary embodiment of the present invention; and

FIG. 3 illustrates an exemplary user interface of the electronic book of FIG. 2, in accordance with an exemplary embodiment of the present invention.

Like reference numerals refer to like parts throughout the description of several views of the drawings.

### DETAILED DESCRIPTION OF THE INVENTION

The exemplary embodiments described herein detail for illustrative purposes are subject to many variations in structure and design. It should be emphasized, however, that the present invention is not limited to a particular closure, as shown and described. It is understood that various omissions and substitutions of equivalents are contemplated as circumstances may suggest or render expedient, but these are intended to cover the application or implementation without departing from the spirit or scope of the claims of the present invention.

The terms “first,” “second,” and the like, herein do not denote any order, quantity, or importance, but rather are used to distinguish one element from another, and the terms “a” and “an” herein do not denote a limitation of quantity, but rather denote the presence of at least one of the referenced item.

The present invention provides a portable electronic book system. The portable electronic book system enables a user to access any books without requiring him/her to use physical books. For example, the portable electronic book system enables a child to access his/her text books without requiring him/her to carry the text books in bags. More specifically, the portable electronic book system disclosed herein may be incorporated in an electronic device, for example, an electronic book, that is capable of storing content of the textbooks of a user, for example, a child in an electronic format. The electronic format of the content of the textbooks of the user may be downloaded into the electronic book by the user. Thereafter, the user may access the downloaded content stored in the electronic book, whenever desired.

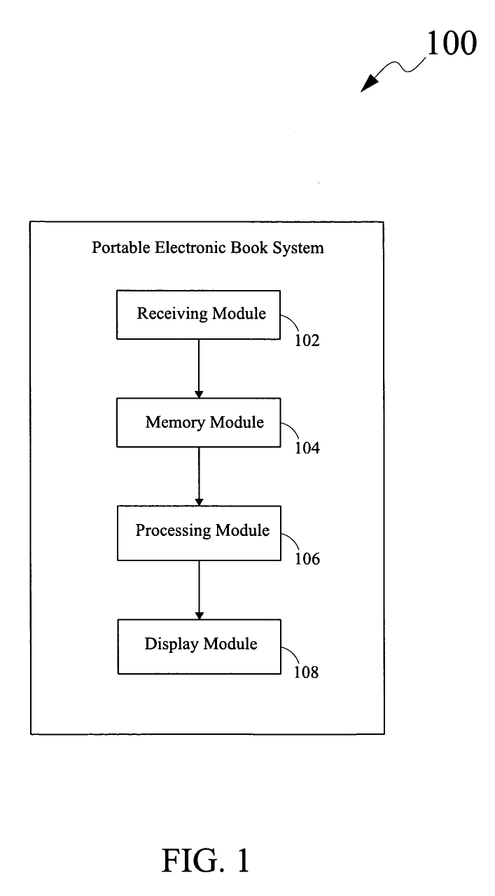

Referring to FIG. 1, a block diagram of a portable electronic book system 100, in accordance with an embodiment of the present invention is illustrated. The portable electronic book system 100 (hereinafter referred to as system 100) includes at least one receiving module 102 (hereinafter referred to as receiving module 102), a memory module 104, a processing module 106, and a display module 108. The receiving module 102 receives an electronic data from at least one machine readable storage medium (hereinafter referred to as “the storage medium”). Preferably, the electronic data is associated with content of at least one textbook of a user, for example, a child. For instance, the electronic data may include electronic contents of various textbooks used by the child in the school. The electronic contents may relate to numerous chapters present in the various textbooks. Moreover, the electronic data may be in a format such as an image format, a Portable Document Format (PDF), a Hypertext Markup Language (HTML) format and any other formats known in the art.

In an embodiment of the present invention, the receiving module 102 may be implemented as an optical disc drive adapted to receive the storage medium containing the electronic data. The optical disc drive reads or decodes the electronic data from the storage medium. Moreover, the storage medium may include a Compact Disc Read Only Memory (CD-ROM), a Compact Disc Recordable (CD-R) and a Digital Video Disc (DVD).

In another embodiment of the present invention, the receiving module 102 is an interface port. More specifically, the interface port may be a Universal Serial Bus (USB) port. The USB port may read the electronic data from the storage medium. In the present embodiment, the storage medium may be a flash memory.

The memory module 104 is operatively coupled to the receiving module 102. The memory module 104 is adapted to store the decoded electronic data received from the receiving module 102. The memory module 104 may include a Read Access Memory (RAM), a Read Only Memory (ROM), a flash memory or any programmable memory.

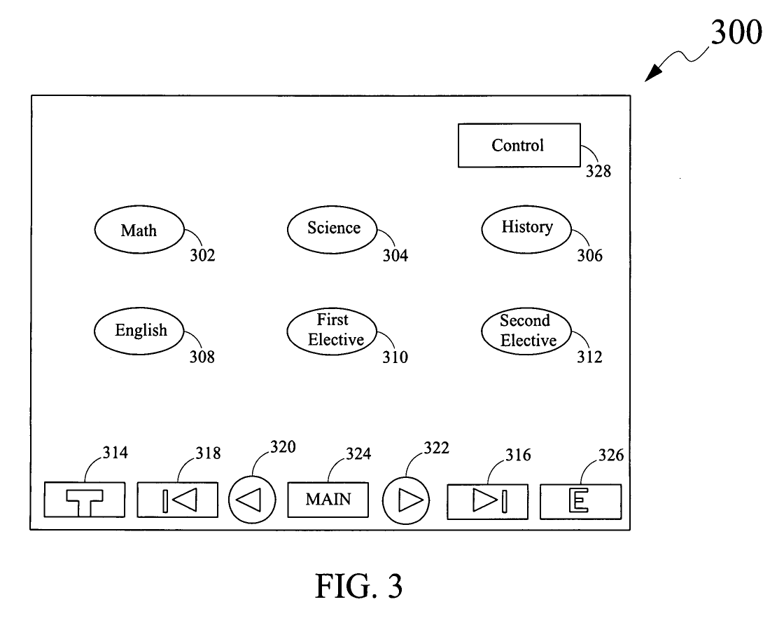

The decoded electronic data stored in the memory module 104 is processed by the processing module 106. More specifically, the processing module 106 operatively coupled with the memory module 104 and the processing module 106 is adapted to retrieve the stored electronic data from the memory module 104. In an embodiment of the present invention, the processing module 106 retrieves the stored electronic data upon receiving a request from the user. For instance, a student using an electronic book incorporating the system 100 may input a request for providing the electronic data such as the electronic contents of the various text books in the electronic book. Based on the request, the processing module 106 retrieves the electronic data from the memory module 104. Without limiting the scope of the present invention, the request for providing the electronic data may be received and processed by the processing module 106. A process of inputting the request for providing the electronic data in the electronic book, by the user will be explained further in conjunction with FIG. 3.

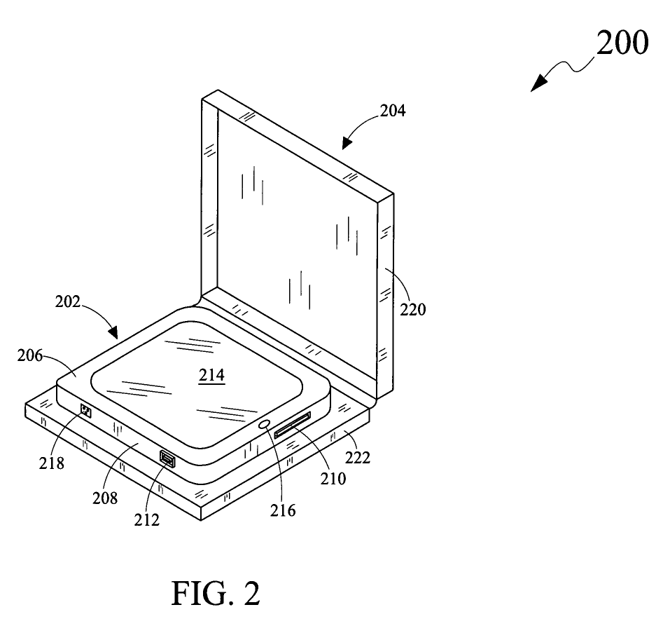

The processing module 106 is further adapted to processes the decoded electronic data to form a processed electronic data. More specifically, the processed electronic data may be in a format that can be displayed in a display screen of the electronic book that incorporates the system 100. The electronic book will be explained further in conjunction with FIG. 2.

The display module 108 is operatively coupled to the processing module 106. The display module 108 is adapted to receive the processed electronic data from the processing module 106 and to display the processed electronic data. More specifically, the display module 108 displays the processed electronic data in the display screen of the electronic book. In an embodiment of the present invention, the display module 108 may be implemented as a touch screen display configured with the display screen for displaying the processed electronic data. The display of the processed electronic data on the display screen of the electronic book during a utilization of the electronic book by the user will be explained further in conjunction with FIG. 3.

Moreover, the receiving module 102, the processing module 106 and the display module 108 may be supplied with electrical power by a power source configured in the electronic book incorporating the system 100. More specifically, the power source may be operatively coupled to the receiving module 102, the processing module 106 and the display module 108 for supplying the electrical power thereto. The power source will be explained further in conjunction with FIG. 2.

It will be evident to those skilled in the art that each of the modules of the system 100 such as the receiving module 102, the memory module 104, the processing module 106, and the display module 108 may be implemented as a hardware module, a software module, a firmware module, or any combination thereof. Furthermore, it will be obvious to those skilled in the art that the system 100 may include requisite electrical connections for communicably coupling the various modules of the system 100.

Referring to FIG. 2, a perspective view of an electronic book 200 incorporating the system 100 of FIG. 1, in accordance with an exemplary embodiment of the present invention is illustrated. The electronic book 200 includes a housing 202 and a cover assembly 204. The housing 202 includes a top surface 206, a bottom surface (not shown) and four side walls 208 (hereinafter referred to as “the walls 208”) extending between the top surface 206 and the bottom surface. The housing 202 includes an optical disc drive 210, an interface port 212, a display screen 214, a power switch 216 and a power slot 218.

The electronic book 200 is capable of receiving the electronic data such as the electronic contents of the various books through the optical disc drive 210. More specifically, the optical disc drive 210 configured at one of the walls 208 of the housing 202. The optical disc drive 210 is adapted to receive the storage medium containing the electronic data. It will be apparent to a person skilled in the art that the optical disk drive 210 may be configured at any other portion of the housing 202 of the electronic book 200.

As discussed in conjunction with FIG.1, the optical disc drive 210 may include a CD-ROM drive, a DVD drive and the Combo drive. Further, the storage medium may include the CD-ROM, the CD-R and the DVD. For instance, a user such as a child or a student may insert a CD-ROM containing the electronic data such as the electronic contents of the various text books used by the child in the optical disc drive 210 such as a CD-ROM drive. The optical disc drive 210 decodes the electronic data from the CD-ROM.

In an embodiment of the present invention, the electronic data is received by the electronic book 200 through the interface port 212 configured at the housing 202. More specifically, the interface port 212 may be configured at one of the walls 208 of the housing 202 as depicted in FIG. 2. It will be apparent to a person skilled in the art that the one or more interface ports such as the interface port 212 may be configured at one of the walls of the housing 202. As discussed in conjunction with FIG. 1, the interface port 212 may be a Universal Serial Bus (USB) port adapted to receive the electronic data from the storage medium such as the flash memory.

The electronic book 200 may include a memory (not shown) such as the memory module 104, for storing the electronic data received either through the optical disc drive 210 or the interface port 212. As discussed in conjunction with FIG. 1, the memory may include the Read Access Memory (RAM), the Read Only Memory (ROM), the flash memory or the any programmable memory.

The electronic book 200 is capable of displaying the stored electronic data through the display screen 214. The display screen 214 is configured on the top surface 206 of the housing 202. The display screen 214 is configured to display the electronic data such as the electronic contents of the various books upon receiving the request for providing the electronic data from the user. For instance, the display screen 214 may display the contents of the various textbooks used by the child in the school in an electronic format. In an embodiment of the present invention, the display screen 214 may be a touch screen display for enabling the user to input the request for the electronic data by touching the display screen using his/her finger or a stylus.

Moreover, the electronic book 200 is configured with the power switch 216. In an embodiment of the present invention, the power switch 216 may be configured at the top surface 206 of the housing 202. The power switch 216 is used by a user to switch ON or switch OFF the electronic book 200. Further, the electronic book 200 is configured with a power source (not shown) for providing electrical power to the electronic book 200. More specifically, the electrical power supplied by the power source may be used to operate the display screen 214 and the optical disc drive 210 of the electronic book 200.

In an embodiment of the present invention, the power source may be a rechargeable battery. However, it will be apparent to a person skilled in the art that the power source may include one or more rechargeable batteries or any other batteries that may be capable of supplying the electrical power to the electronic book 200. The rechargeable battery may be recharged using an external power source. More specifically, the external source may be connected to the power slot 218 configured in the electronic book 200. The external power source supplies the electrical power to recharge the rechargeable battery. In an embodiment of the present invention, the power slot 218 may be configured at one of the walls 208 of the electronic book 200 as depicted in FIG. 2. In an embodiment of the present invention, the power slot 218 may be adapted to receive the electrical power through an adapter such as A/C adapter connected to the external power source. In an alternate embodiment of the present invention, the electronic book 200 may be capable of operating upon receiving the electrical power from the external power source.

Furthermore, the electronic book 200 may be provided with the cover assembly 204 adapted to cover the housing 202. In an embodiment of the present invention, the cover assembly 204 may include a first cover portion 220 and a second cover portion 222. The first cover portion 220 may be operatively coupled to the second cover portion 222. The first cover portion 220 may be adapted to be disposed on the top surface 206 of the housing 202 covering the housing 202 upon operatively moving the first cover portion 220. It will be apparent to a person skilled in the art that the first cover portion 220 may be hingedly or pivotally coupled with the second cover portion 222. Further, the housing 202 may be disposed on the second cover portion 222.

In an alternate embodiment of the present invention, the cover assembly 204 may be pivotally coupled to one of the walls 208 of the housing 202. The cover assembly 204 may be adapted to be disposed on the top surface 206 of the housing 202 covering the housing 202 upon pivotally moving the cover assembly 204. In an embodiment of the present invention, the cover assembly 204 may be composed of any material known in the art that enables the cover assembly 204 to be durable.

It will be obvious to a person skilled in the art that such a configuration of the electronic book 200 is an exemplary representation and should not be considered as a limitation of the system 100. A variety of other configurations of the electronic book 200 may be used in the present invention.

Referring to FIG. 3, an exemplary user interface (UI) 300 of the electronic book 200, in accordance with an exemplary embodiment of the present invention is illustrated. As explained in conjunction with FIG. 1, the display module 108 may be implemented as the touch screen display with the display screen 214. The display module 108 may configure the display screen 214 to provide the UI 300. The UI 300 includes a plurality of subject tabs pertaining to various subjects. For example, as illustrated in FIG. 3, the UI 300 includes various tabs, such as a Math tab 302, a Science tab 304, a History tab 306, an English tab 308, a First Elective Tab 310 and a Second Elective Tab 312.

The UI 300 enables the user, such as a student, to select a subject of his/her choice using the plurality of tabs such as the Math tab 302, the Science tab 304, the History tab 306, the English tab 308, the First Elective Tab 310 and the Second Elective Tab 312. More specifically, the user may select the Math tab 302, the Science tab 304, the History tab 306, the English tab 308, the First Elective Tab 310 and the Second Elective Tab 312 to select the subjects such as Math, Science, History, English, a First elective subject and a Second elective subject, respectively. In an embodiment of the present invention, the user may use his/her finger or a stylus to touch the plurality of tabs displayed on the display screen 214 for selecting a subject from the subjects. Upon selecting the subject for example, Math, the request for providing the electronic data such as a request for providing electronic contents of the selected subject may be received by the system 100. More specifically, the request for electronic data associated with the selected subject may be received and processed by the processing module 106 of the system 100. Based on the request, the processing module 106 retrieves the electronic data associated with the selected subject from the memory module 104 of the system 100.

Thereafter, the electronic data associated with the selected subject are displayed in the UI 300. Further, the UI 300 provides a plurality of navigating tabs for enabling the user to navigate through the electronic data associated with the selected subject. The plurality of navigating tabs may include a contents tab 314, a next chapter tab 316, a previous chapter tab 318, a previous page tab 320 and a next page tab 322. The contents tab 314 may enable the user to view the electronic data related to the selected subject through the UI 300. More specifically, once the contents tab 314 is selected by the user, a table of contents pertaining to the selected subject is displayed in the UI 300. In an embodiment of the present invention, the table of contents may include a list of chapters associated with the selected subject. Thereafter, the user may select a chapter of his/her choice from the table of contents through the UI 300.

Further, the next chapter tab 316 may allow the user to move to a next chapter from the selected chapter. Once the user has moved to the next chapter, the user may select the previous chapter tab 318 to access a previously accessed chapter such as the selected chapter. Moreover, the user may select the previous page tab 320 and the next page tab 322 for accessing a previously accessed page and a next page after a presently accessed page, respectively.

Moreover, the UI 300 provides a main menu tab 324 that may enable the user to move to a main menu that lists the plurality of tabs such as the Math tab 302, the Science tab 304, the History tab 306, the English tab 308, the First Elective Tab 310 and the Second Elective Tab 312. Furthermore, the UI 300 provides an exit tab 326 that may allow the user to exit from any content presently viewed by the user. Moreover, the UI 300 is provided with a control tab 328 that may enable the user to adjust settings of the display screen 214. The settings may include color, contrast, brightness, and so on. For instance, the user may use the control tab 328 to adjust the brightness or the color or the contrast of the display screen 214 according to the user's choice.

It will be obvious to a person skilled in the art that such a configuration of the UI 300 provided by the display screen 214 is an exemplary representation and should not be considered as a limitation of the system 100. A variety of other configurations of the UI 300 may be used in the present invention.

The portable electronic book system explained in conjunction with FIGS. 1, 2 and 3 may be advantageously used by a user for viewing contents of text books in an electronic format without requiring the user to carry any physical text books. Moreover, the portable electronic book may simplify a learning experience of the user such as a student by combining contents of several books into a single device such as the electronic book. Further, the portable electronic book precludes a need for the user such as the student to carry several text books in a bag, such a backpack while going to a school or a college. Additionally, a usage of the portable electronic book eliminates a need for buying bags frequently that may deteriorate due to constant usage, and thus saves time and money of the user. Furthermore, the portable electronic book may be light-weight and durable, thereby enabling an easy portability thereof.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The embodiments were chosen and described in order to best explain the principles of the present invention and its practical application, and to thereby enable others skilled in the art to best utilize the present invention and various embodiments with various modifications as are suited to the particular use contemplated. It is understood that various omissions and substitutions of equivalents are contemplated as circumstances may suggest or render expedient, but such omissions and substitutions are intended to cover the application or implementation without departing from the spirit or scope of the claims of the present invention.

What is claimed is:

1. A portable electronic book system comprising:
at least one receiving module adapted to receive an electronic data from at least one machine readable storage medium, the electronic data being associated with content of at least one textbook of a user;
a memory module operatively coupled to the at least one receiving module, the memory module adapted to store the electronic data received from the at least one receiving module;
a processing module operatively coupled to the memory module, the processing module adapted to retrieve the stored electronic data from the memory module, and process the retrieved electronic data; and
a display module operatively coupled to the processing module, the display module adapted to display the processed electronic data.

2. The portable electronic book system of claim 1, wherein the at least one receiving module is an optical disk drive.

3. The portable electronic book system of claim 2, wherein the at least one machine readable storage medium is a Compact Disc-Read Only Memory (CD-ROM) disc.

4. The portable electronic book system of claim 2, wherein the at least one machine readable storage medium is a Digital Video Disc-Read Only Memory (DVD-ROM) disc.

5. The portable electronic book system of claim 1, wherein the at least one receiving module is an interface port.

6. The portable electronic book system of claim 5, wherein the interface port comprises a Universal Serial Bus (USB) port.

7. The portable electronic book system of claim 5, wherein the at least one machine readable storage medium comprises a flash memory.

8. The portable electronic book system of claim 1, wherein the display module is a touch sensitive display screen.
